(19) United States
(12) Patent Application Publication
(10) Pub. No.: US 2026/0363074 A1
(43) Pub. Date: Nov. 12, 2026

(54) SEMICONDUCTOR PACKAGES AND METHODS OF FORMING SAME

(71) Applicant: Taiwan Semiconductor Manufacturing Co., Ltd., Hsinchu (TW)

(72) Inventors: Meng-Wei Chou, Zhubei City (TW); Yu-Hsiang Hu, Hsinchu (TW); Jyun-Siang Peng, Hsinchu (TW); Hsin-Yu Chen, Taipei City (TW); Chien-Hsun Lee, Chu-tung Town (TW)

(21) Appl. No.: 19/733,084

(22) Filed: Jul. 7, 2026

Related U.S. Application Data
(63) Continuation of application No. 18/923,334, filed on Oct. 22, 2024.
(60) Provisional application No. 63/659,892, filed on Jun. 14, 2024.

(51) Int. Cl. H10W 40/25; H10W 42/00; H10W 72/00; H10W 74/01; H10W 74/10; H10W 74/15; H10W 90/00

(52) U.S. Cl. CPC H10W 40/258; H10W 42/121; H10W 74/016; H10W 74/117; H10W 74/121; H10W 72/0198; H10W 74/15; H10W 90/00; H10W 90/724; H10W 90/734

(57) ABSTRACT

A method includes forming a thermal layer stack covering a top surface of a package component, wherein the thermal layer stack includes sublayers of different metals; connecting the package component to a package substrate; depositing a molding material on the package substrate and on the package component; and attaching a support ring to the molding material.

### PRIORITY CLAIM AND CROSS-REFERENCE

This application is a continuation of U.S. patent application Ser. No. 18/923,334, filed on Oct. 22, 2024, which claims the benefit of U.S. Provisional Application No. 63/659,892, filed on Jun. 14, 2024, each application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, and 7 illustrate cross-sectional views of intermediate steps during a process for forming a package component, in accordance with some embodiments.

FIGS. 8, 9, 10, and 11 illustrate cross-sectional views of intermediate steps during a process for forming a package, in accordance with some embodiments.

FIGS. 12A and 12B illustrate cross-sectional views of thermal layers, in accordance with some embodiments.

FIGS. 13, 14, 15, and 16 illustrate cross-sectional views of intermediate steps during a process for forming a package, in accordance with some embodiments.

FIG. 17 illustrates a cross-sectional view of an intermediate step during a process for forming a package, in accordance with some embodiments.

FIGS. 18, 19, 20, 21, 22, 23, and 24 illustrate cross-sectional views of intermediate steps during a process for forming a package, in accordance with some embodiments.

FIGS. 25, 26, 27, 28, 29, and 30 illustrate cross-sectional views of intermediate steps during a process for forming a package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a thermally conductive layer is formed on a top surface of a package component of a package. The thermally conductive layer may comprise one or more layers of metals that allow for improved dissipation of heat from the package component. A molding material (e.g., an encapsulant) can be formed on the package substrate of the package and around the package component of the package to provide improved structural support and reduce warpage of the package. One or more support rings can be attached to the molding material to provide additional structure support and further reduce warpage. In some embodiments, multiple support rings of different composition can be stacked on the molding material, which can further enhance thermal stability and reduce warpage.

Various embodiments are described below in a particular context. Specifically, a chip on wafer on substrate type system on integrated chip (SoIC) package is described. However, various embodiments may also be applied to other types of packaging technologies, such as integrated fan-out (InFO) packages or the like.

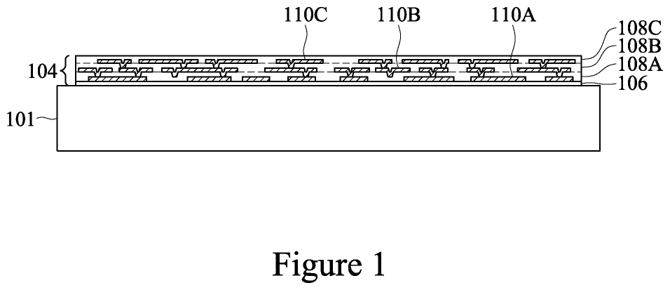

FIGS. 1 through 7 illustrate cross-sectional views of intermediate steps during a process for forming a package component 100, in accordance with some embodiments. In FIG. 1, a redistribution structure 104 is formed on a carrier substrate 101, in accordance with some embodiments. The carrier substrate 101 may be, for example, a glass carrier substrate, a ceramic carrier substrate, a panel, or the like. The carrier substrate 101 may be a wafer, such that multiple packages can be formed on the carrier substrate 101 simultaneously. The carrier substrate 101 may be a bulk material that is free of any active or passive devices, for example.

In some embodiments, a release layer (not illustrated) is formed on the carrier substrate 101 prior to formation of the redistribution structure 104. The release layer may be formed of a polymer-based material, which may be removed along with the carrier substrate 101 from the overlying structures that will be formed in subsequent steps. In some embodiments, the release layer is an epoxy-based thermal-release material, which loses its adhesive property when heated, such as a light-to-heat-conversion (LTHC) release coating. In other embodiments, the release layer may be an ultra-violet (UV) glue, which loses its adhesive property when exposed to UV lights. The release layer may be dispensed as a liquid and cured, may be a laminate film laminated onto the carrier substrate 101, or may be the like. The top surface of the release layer may be leveled and may have a high degree of planarity.

In the embodiment shown, the redistribution structure 104 includes a dielectric layer 106, dielectric layers 108 (labeled 108A, 108B, and 108C), and metallization patterns 110 (labeled 110A, 110B, and 110C). In some cases, the dielectric layers 106 and 108 may be considered passivation layers or insulating layers, and the metallization patterns 110 may be considered redistribution layers or redistribution lines. Other numbers or configurations of dielectric layers or metallization patterns are possible.

The dielectric layer 106 is formed on the carrier substrate 101, and may be formed on the release layer, if present. The bottom surface of the dielectric layer 106 may be in contact with the top surface of the carrier substrate 101, in some embodiments. In some embodiments, the dielectric layer 106 is formed of a polymer, such as polybenzoxazole (PBO), polyimide, benzocyclobutene (BCB), or the like. In other embodiments, the dielectric layer 106 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 106 may be formed by any acceptable deposition process, such as spin coating, chemical vapor deposition (CVD), laminating, the like, or a combination thereof. In some embodiments, the dielectric layer 106 may be free of any metallization patterns and may protect overlying metallization patterns 110 from damage when the carrier substrate 101 is subsequently removed.

The metallization pattern 110A is formed on the dielectric layer 106. As an example to form metallization pattern 110A, a seed layer (not separately illustrated) may be formed over the dielectric layer 106. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist (not shown) is then formed and patterned on the seed layer. The photoresist may be formed by spin coating or the like and may be exposed to light for patterning. The pattern of the photoresist corresponds to the metallization pattern 110A. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization pattern 110A.

The dielectric layer 108A is formed on the metallization pattern 110A and the dielectric layer 106. The dielectric layer 108A may be formed in a manner similar to the dielectric layer 106, and may be formed of a similar material as the dielectric layer 106. In some embodiments, the dielectric layer 108A is formed of a polymer, which may be a photo-sensitive material such as PBO, polyimide, BCB, or the like, that may be patterned using a lithography mask. In other embodiments, the dielectric layer 108A is formed of a nitride such as silicon nitride; an oxide such as silicon oxide, PSG, BSG, BPSG; or the like. The dielectric layer 108A may be formed by spin coating, lamination, CVD, the like, or a combination thereof. The dielectric layer 108A is then patterned to form openings exposing portions of the metallization pattern 110A. The patterning may be performed using an acceptable process, such as by exposing the dielectric layer 108A to light when the dielectric layer 108A is a photo-sensitive material or by etching using, for example, an anisotropic etch. If the dielectric layer 108A is a photo-sensitive material, the dielectric layer 108A can be developed after the exposure.

Alternatively, in other embodiments that are not specifically illustrated, the dielectric layer 108A may be deposited prior to forming the metallization pattern 110A. For example, the dielectric layer 108A may be deposited of a similar material using a similar process as described above. After deposition, a damascene process (e.g., a dual damascene process or a single damascene process) may be used to pattern openings in the dielectric layer 108A. The patterning of the openings may correspond to a pattern of the metallization pattern 110A. The metallization pattern 110A may then be deposited in the openings, e.g., using a plating process. The metallization pattern 110A may initially overflow the openings, and a planarization process (e.g., a CMP process or the like) may be used to level top the dielectric layer 108A and the metallization pattern 110A.

Additional metallization patterns 110B and 110C may be formed over the metallization pattern 110A in dielectric layers 108B and 108C, respectively. Specifically, the metallization pattern 110B is formed in dielectric layer 108B, which is disposed over the dielectric layer 108A and the metallization patterns 110A. Further, the metallization pattern 110C is formed in dielectric layer 108C, which is disposed over the dielectric layer 108B and the metallization pattern 110B. Each of the dielectric layers 108B and 108C may by formed of a similar material and using similar processes as described above with respect to the dielectric layer 108A. Further, each of the metallization patterns 110B and 110C may be formed of a similar material and using similar processes as described above with respect to the metallization pattern 110A.

The dielectric layers 108 may have thicknesses in the range of about 20 μm to about 50 μm, though other thicknesses are possible. In some embodiments, different dielectric layers 108 of the redistribution structure 104 (e.g., dielectric layers 108A, 108B, and/or 108C) have different thicknesses. The metallization patterns 110 may have a line width in the range of about 0.5 μm to about 3 μm, though other line widths are possible. In some embodiments, different metallization patterns 110 of the redistribution structure 104 (e.g., metallization patterns 110A, 110B, and/or 110C) have different sizes. For example, in some embodiments, the conductive lines and/or vias of the metallization pattern 110B or 110C may be wider or thicker than the conductive lines and/or vias of the metallization pattern 110A. As another example, the metallization pattern 110B or 110C may be formed to a greater pitch than the metallization pattern 110A. Other combinations of different sizes or pitches are possible.

FIG. 1 illustrates a redistribution structure 104 having a specific number of metallization patterns 110 for illustrative purposes. However, the redistribution structure 104 may include any number of dielectric layers 108 or metallization patterns 110. If fewer dielectric layers 108 and metallization patterns 110 are to be formed in the redistribution structure 104, steps and processes discussed above may be omitted. If more dielectric layers 108 and metallization patterns 110 are to be formed in the redistribution structure 104, steps and processes discussed above may be repeated. The additional metallization patterns 110 may include one or more conductive elements, such as conductive lines, conductive vias, or the like. The conductive elements may be formed during the formation of the metallization pattern 110 by forming the seed layer and conductive material of the metallization pattern over a surface of the underlying dielectric layer and in the opening of the underlying dielectric layer, thereby interconnecting and electrically coupling various conductive lines. Further, the completed redistribution structure 104 may be free of any active devices and/or free of any passive devices.

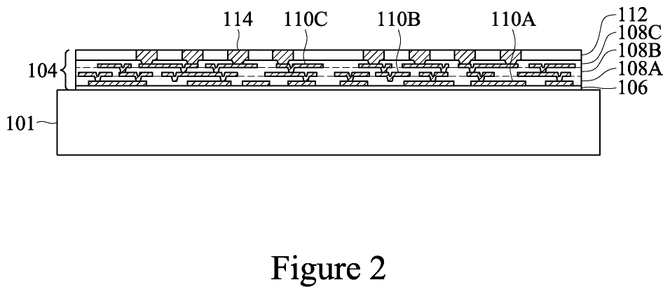

In FIG. 2, a dielectric layer 112 is deposited on the dielectric layer 108C, in accordance with some embodiments. In other embodiments in which more or fewer dielectric layers 108 are formed, the dielectric layer 112 is deposited on the top-most dielectric layer 108. The dielectric layer 112 may be formed in a manner similar to the dielectric layers 108, and may be formed of the same material as the dielectric layers 108. In some embodiments, the dielectric layer 112 may be a passivation layer or a solder resist layer.

Further in FIG. 2, under bump metallizations (UBMs) 114 are formed for external connection to the redistribution structure 104. The UBMs 114 have bump portions on and extending along the major surface of the dielectric layer 112, and have via portions extending through the dielectric layer 112 and the dielectric layer 108C to physically and electrically couple the metallization pattern 110C. In other embodiments in which more or fewer metallization patterns 110 are formed, the UBMs 114 extend through the dielectric layer 112 and the top-most dielectric layer 108 to contact the top-most metallization pattern 110. The dielectric layer 112 and the UBMs 114 may be considered part of the redistribution structure 104, in some cases.

As an example of forming the UBMs 114, openings are formed through the dielectric layer 112 and the dielectric layer 108C to expose portions of the metallization pattern 110C. The openings may be formed, for example, using laser drilling, etching, or the like. The material(s) of the UBMs 114 are formed in the openings. In some embodiments, the UBMs 114 include three layers of conductive materials, such as a first layer of copper, a layer of nickel, and a second layer of copper. Other arrangements of materials and layers, such as an arrangement of titanium/copper/nickel, an arrangement of chrome/chrome-copper alloy/copper/gold, an arrangement of titanium/titanium tungsten/copper, or an arrangement of copper/nickel/gold, may be utilized for the formation of the UBMs 114. In some embodiments, the layers of conductive materials may have thicknesses in the range of about 1 μm to about 20 μm, such that the total thickness of all layers is less than about 80 μm. Other thicknesses or total thicknesses are possible. In other embodiments, the UBMs 114 comprise flux and are formed in a flux dipping process. In other embodiments, the UBMs 114 comprise a conductive paste such as solder paste, silver paste, or the like, and are dispensed in a printing process. In other embodiments, the UBMs 114 are formed in a manner similar to the metallization patterns 110, and may be formed of a similar material as the metallization patterns 110. In some embodiments, the UBMs 114 have a different size than the metallization patterns 110A, 110B, and/or 110C. For example, the UBMs 114 may be thicker than the metallization patterns 110A, 110B, and/or 110C. In some embodiments, the UBMs 114 may be bond pads, conductive pads, conductive pillars, or the like. Other formation techniques or materials are possible.

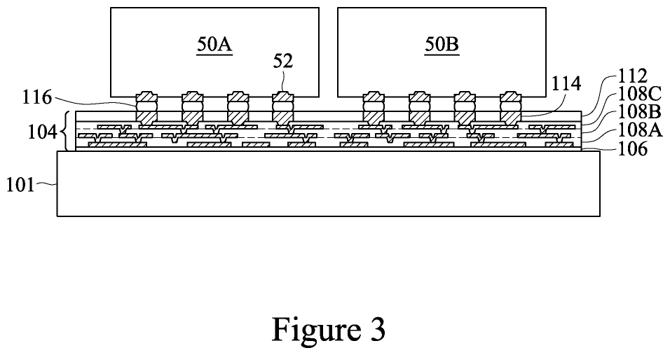

In FIG. 3, one or more integrated circuit dies 50 are bonded to the redistribution structure 104 by conductive connectors 116, in accordance with some embodiments. The integrated circuit dies 50 are physically and electrically connected to the redistribution structure 104 by the conductive connectors 116. FIG. 3 illustrates a first integrated circuit die 50A and a second integrated circuit die 50B bonded to the redistribution structure 104, but any suitable number of integrated circuit dies 50 may be bonded to the redistribution structure 104. In the embodiment shown, multiple integrated circuit dies 50 are bonded adjacent one another. In some embodiments, the integrated circuit dies 50 may be semiconductor devices, chips, packages, or the like. The integrated circuit dies 50 may include a logic device, such as a central processing unit (CPU), a graphics processing unit (GPU), a system-on-a-chip (SoC), a microcontroller, or the like. The integrated circuit dies 50 may include a memory device, such as a dynamic random access memory (DRAM) die, a static random access memory (SRAM) die, a hybrid memory cube (HMC) module, a high bandwidth memory (HBM) module, or the like.

In some embodiments, the integrated circuit dies 50 bonded to the redistribution structure 104 may be the same type of dies, such as SoC dies. In other embodiments, the integrated circuit dies 50 bonded to the redistribution structure 104 include different types of dies. The integrated circuit dies 50 may be formed in processes of a same technology node, or may be formed in processes of different technology nodes. For example, the first integrated circuit die 50A may be of a more advanced process node than the second integrated circuit die 50B. The integrated circuit dies 50 may have different sizes (e.g., different heights and/or surface areas), or may have the same size (e.g., same heights and/or surface areas). Other combinations of integrated circuit dies 50 are also possible in other embodiments. In some embodiments, the integrated circuit dies 50 may have a thickness in the range of about 400 μm to about 800 μm, though other thicknesses are possible.

The conductive connectors 116 are formed on the UBMs 114, in some embodiments. The conductive connectors 116 may be ball grid array (BGA) connectors, solder balls, solder bumps, metal pillars, controlled collapse chip connection (C4) bumps, micro bumps, electroless nickel-electroless palladium-immersion gold technique (ENEPIG) formed bumps, or the like. The conductive connectors 116 may include a conductive material such as solder, copper, aluminum, gold, nickel, silver, palladium, tin, the like, or a combination thereof. In some embodiments, the conductive connectors 116 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 116 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In some embodiments, the conductive connectors 116 are formed on the integrated circuit dies 50 in addition to or instead of being formed on the UBMs 114. The integrated circuit dies 50 may be bonded to the redistribution structure 104, for example, by forming conductive connectors 116 on the UBMs 114, placing conductive regions of the integrated circuit dies 50 on the conductive connectors 116, and then performing a reflow process on the conductive connectors 116 to bond the integrated circuit dies 50 to the redistribution structure 104.

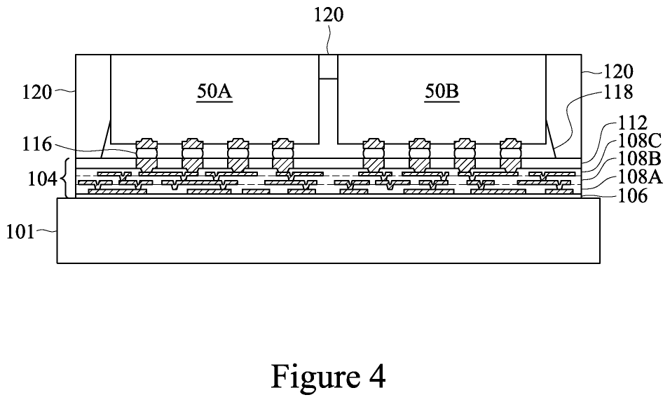

In FIG. 4, an underfill 118 is formed between the integrated circuit dies 50 and the redistribution structure 104, surrounding the conductive connectors 116. The underfill 118 may reduce stress and protect the joints resulting from the reflowing of the conductive connectors 116. The underfill 118 may be formed by a capillary flow process after the integrated circuit dies 50 are attached, or may be formed by a suitable deposition method before the integrated circuit dies 50 are attached. In other embodiments, the underfill 118 is not formed.

An encapsulant 120 is then formed over the redistribution structure 104 and the integrated circuit dies 50, in accordance with some embodiments. After formation, the encapsulant 120 encapsulates the integrated circuit dies 50, and the encapsulant 120 may contact a top surface of the dielectric layer 112. The encapsulant 120 may be a molding compound, an epoxy, or the like. The encapsulant 120 may be applied by compression molding, transfer molding, deposition, or the like, and may be formed over the redistribution structure 104 such that the integrated circuit dies 50 are buried or covered. The encapsulant 120 is further formed in gap regions between the integrated circuit dies 50. The encapsulant 120 may be applied in liquid or semi-liquid form and then subsequently cured.

After the encapsulant 120 is formed, a planarization process may be performed on the encapsulant 120 to expose one or more of the integrated circuit dies 50. The planarization process may also remove material of the integrated circuit dies 50 that are exposed while other ones of the integrated circuit dies 50 may remain buried in the encapsulant 120 after planarization. Top surfaces of the encapsulant 120 and/or one or more integrated circuit dies 50 may be substantially level or coplanar after the planarization process within process variations. The planarization process may comprise, for example, a chemical-mechanical polish (CMP) process, a grinding process, an etching process, the like, or a combination thereof. In some embodiments, the planarization process may be omitted. In some embodiments, a thickness of the encapsulant 120 on the redistribution structure 104 may be in the range of about 500 μm to about 700 μm, though other thicknesses are possible.

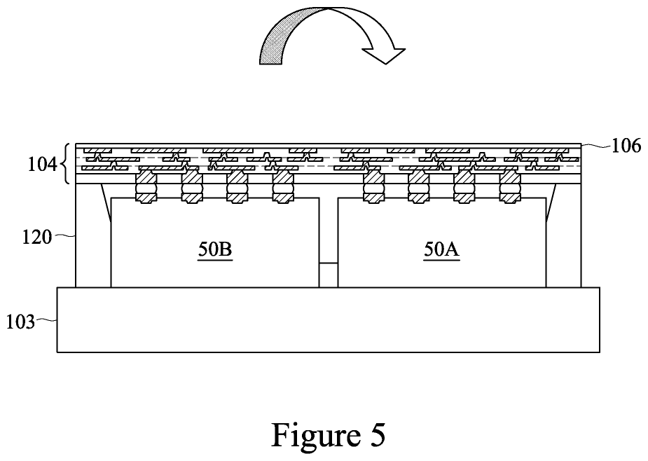

In FIG. 5, the structure is removed from the carrier substrate 101, flipped over, and attached to a different carrier substrate 103, in accordance with some embodiments. In some embodiments, a carrier substrate de-bonding is performed to detach (or “de-bond”) the carrier substrate 101 from the back side of the redistribution structure 104, e.g., the dielectric layer 106. In some embodiments, the de-bonding includes projecting a light such as a laser light or an UV light on the release layer such that the release layer decomposes under the heat of the light and the carrier substrate 101 can be removed. The structure is then flipped over and attached to the carrier substrate 103. In other words, the carrier substrate 101 is removed from the back side of the redistribution structure 104, and the carrier substrate 103 is attached to the top side of the encapsulant 120 and/or integrated circuit dies 50. The carrier substrate 103 may be a substrate, a wafer, panel, a die-attach film (DAF), or the like, which may be similar to the carrier substrate 101. In some embodiments, the structure is attached to the carrier substrate 103 using an adhesive, a release layer, or the like (not illustrated).

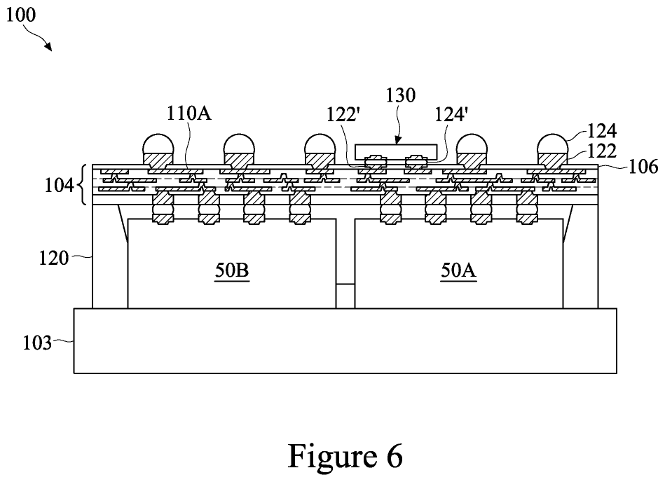

In FIG. 6, conductive connectors 124 are formed on the back side of the redistribution structure 104, in accordance with some embodiments. In some embodiments, UBMs 122 are formed for external connection to the back side of the redistribution structure 104. The UBMs 122 have bump portions on and extending along the major surface of the dielectric layer 106, and have via portions extending through the dielectric layer 106 to physically and electrically couple the metallization pattern 110A of the redistribution structure 104. As a result, the UBMs 122 are electrically coupled to the integrated circuit dies 50. The UBMs 122 may be formed of materials similar to those described previously for the UBMs 114. In some embodiments, the UBMs 122 have a different size or a different pitch than the UBMs 114.

Conductive connectors 124 are formed on the UBMs 122, in some embodiments. The conductive connectors 124 may be similar to the conductive connectors 116 described previously. For example, in some embodiments, the conductive connectors 124 may be solder bumps or the like. In some embodiments, the conductive connectors 124 have a different size or a different pitch than the conductive connectors 116. In some embodiments, the conductive connectors 124 have a thickness in the range of about 75 μm to about 120 μm, though other thicknesses are possible. In some embodiments, the conductive connectors 124 have a pitch in the range of about 100 μm to about 200 μm, though other pitches are possible.

In some embodiments, passive devices 130 (e.g., surface mount devices (SMDs), integrated passive devices (IPDs), or the like) may also be bonded to the back side of the redistribution structure 104. The passive devices 130 may comprise one or more capacitors, inductors, resistors, the like, or combinations thereof. The passive devices 130 may be substantially free of any active devices. The passive devices 130 may be bonded to UBMs 122′ in the redistribution structure 104 using conductive connectors 124′, in some embodiments. The UBMs 122′ may be similar to the UBMs 122 described previously, and the conductive connectors 124′ may be similar to the conductive connectors 124 described previously. In some embodiments, the UBMs 122′ may be smaller than the UBMs 122, and the conductive connectors 124′ may be smaller than the conductive connectors 124. In other embodiments, the passive devices 130 are bonded to the redistribution structure 104 using dielectric-to-dielectric bonding and/or metal-to-metal bonding (e.g., direct bonding, fusion bonding, hybrid bonding, or the like). In such embodiments, the UBMs 122′ may be bond pads. The passive devices 130 are optional, and are not present in some embodiments. In this manner, a package component 100 may be formed, in accordance with some embodiments. Other process steps or manufacturing techniques may be used in other embodiments.

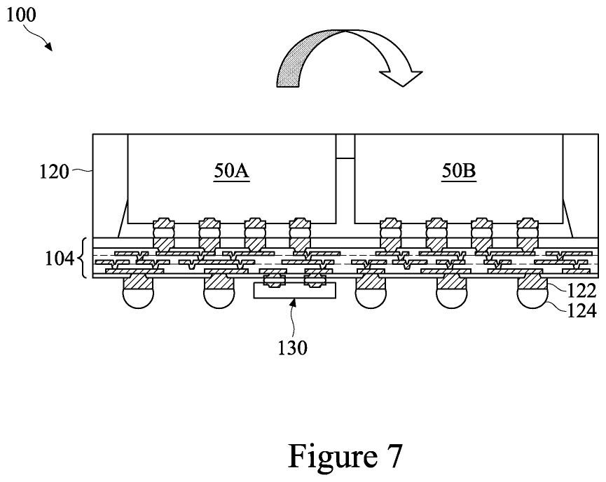

FIG. 7 illustrates a package component 100 after the carrier substrate 103 has been removed, in accordance with some embodiments. In some embodiments, a carrier substrate de-bonding is performed to detach (or “de-bond”) the carrier substrate 103, which may be similar to those described above for FIG. 5. In some embodiments, multiple package components 100 may be formed on the same carrier substrate 101/103 and then singulated to form individual package components 100.

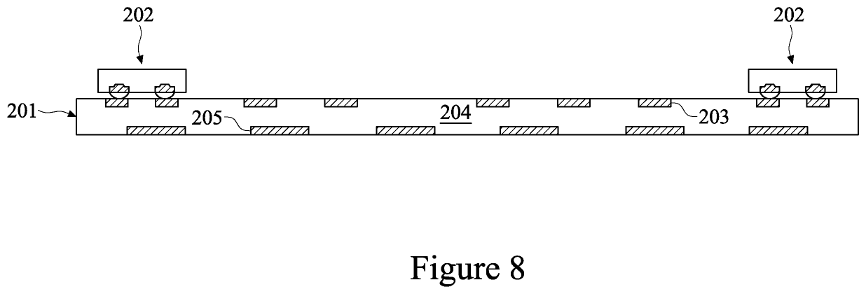

FIGS. 8 through 16 illustrate cross-sectional views of intermediate steps during a process for forming a package 200, in accordance with some embodiments. In FIG. 8, a package substrate 201 is provided, in accordance with some embodiments. In some embodiments, the package substrate 201 includes a substrate core 204, conductive pads 203 at a top side of the substrate core 204, and conductive pads 205. In some embodiments, the package substrate 201 has a thickness in the range of about 1 mm to about 3 mm, though other thicknesses are possible. Other dimensions or areas are possible.

The substrate core 204 may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. In some embodiments, the substrate core 204 is a wafer, a silicon-on-insulator (SOI) substrate, or the like. Generally, an SOI substrate includes a layer of a semiconductor material such as epitaxial silicon, germanium, silicon germanium, SOI, silicon germanium-on-insulator (SGOI), or combinations thereof. The substrate core 204 is, in one alternative embodiment, based on an insulating core such as a fiberglass-reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for the substrate core 204 in other embodiments.

The package substrate 201 may include active and passive devices (not shown). A wide variety of devices such as transistors, capacitors, resistors, combinations of these, and the like may be used to generate the structural and functional requirements of the design for the package 200. The devices may be formed using any suitable methods. The substrate core 204 may also include metallization layers and vias (not separately illustrated), with the conductive pads 203/205 being physically and/or electrically coupled to the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate core 204 is substantially free of active and passive devices. The conductive pads 203/205 may be, for example, UBMs, bond pads, or the like. The conductive pads 203/205 allow for external electrical connections to the metallization layers, active devices, and/or passive devices of the package substrate 201.

In some embodiments, surface mount devices (SMDs) 202 are bonded to the package substrate 201. The SMDs 202 may include chips, chiplets, IPDs, or other passive devices or components. The SMDs 202 may be attached to conductive pads 203 of the package substrate 201 using conductive connectors (e.g., solder bumps or the like) or by direct bonding, such as metal-to-metal bonding or the like. In this manner, the SMDs 202 are physically and electrically connected to the package substrate 201. The SMDs 202 may be attached to the package substrate 201 prior to bonding the package component 100 to the package substrate 201 (described below), or may be attached to the package substrate 201 after bonding the package component 100 to the package substrate 201.

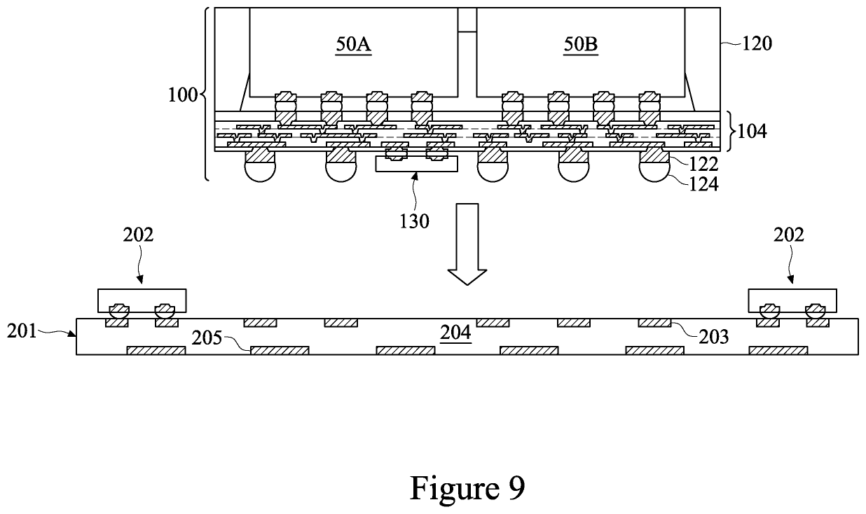

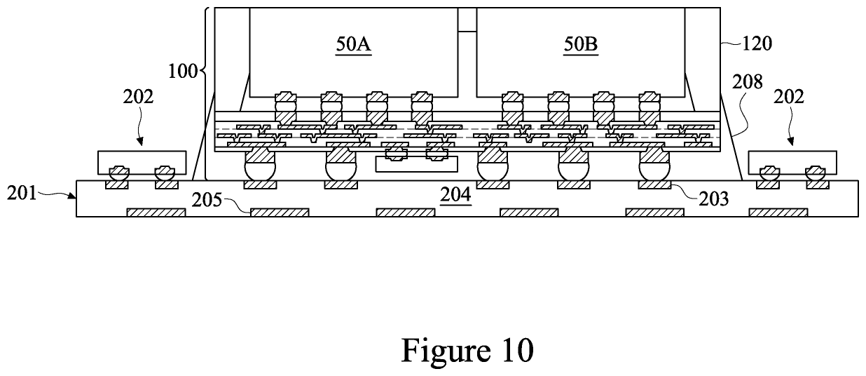

In FIGS. 9 and 10, a package component 100 is bonded to the package substrate 201, in accordance with some embodiments. FIG. 9 illustrates the package component 100 prior to bonding, and FIG. 10 illustrates the package component 100 after bonding. The package component 100 may be similar to the package component 100 described previously for FIG. 7, and may be formed using similar techniques. The package component 100 may be bonded, for example, by placing the conductive connectors 124 of the package component 100 on corresponding conductive pads 203 of the package substrate 201, and then performing a reflow process. After the reflow process, the package component 100 is physically and electrically connected to the package substrate 201. In other embodiments, the package component 100 may be bonded to the package substrate 201 using other techniques, such as metal-to-metal bonding (e.g., direct bonding, fusion bonding, hybrid bonding, or the like).

Referring to FIG. 10, in some embodiments, an underfill 208 is deposited between the package component 100 and the package substrate 201. The underfill 208 surrounds the conductive connectors 124 and the passive device(s) 130. The underfill 208 may reduce stress and protect the joints resulting from the reflowing of the conductive connectors 124. The underfill 208 may be formed by a capillary flow process after the package component 100 is attached, or may be formed by a suitable deposition method before the package component 100 is attached. In other embodiments, the underfill 208 is not formed.

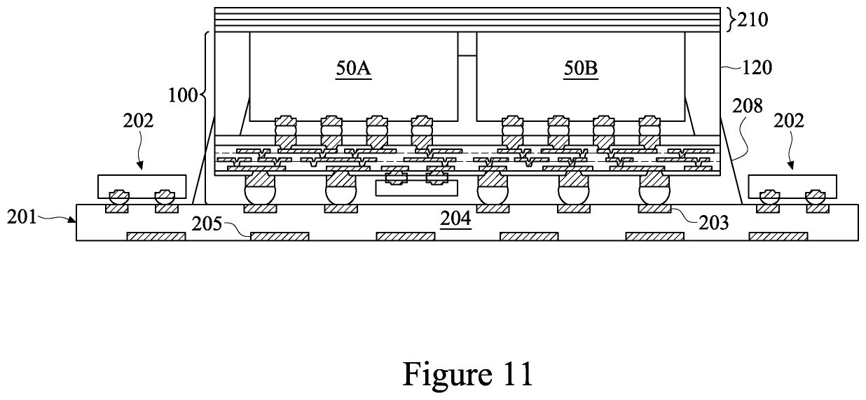

In FIG. 11, a thermal layer 210 is deposited on the package component 100, in accordance with some embodiments. The thermal layer 210 is a thermally conductive layer that facilitates dissipation of heat generated by the integrated circuit dies 50A-B. In this manner, the thermal layer 210 can improve the thermal performance and reliability of the package 200. In some embodiments, the thermal layer 210 is formed on top surfaces of the integrated circuit dies 50A-B and the encapsulant 120. The thermal layer 210 may physically contact top surfaces of the integrated circuit dies 50A-B, which can improve the transfer of heat from the integrated circuit dies 50A-B. In some embodiments, sidewalls of the package component 100 and the thermal layer 210 are coplanar or coterminous. In other embodiments, the thermal layer 210 may have a width that is greater than or less than a width of the package component 100.

The thermal layer 210 may be formed of one or more layers of metal or other thermally conductive material. For example, in some embodiments, the thermal layer 210 may comprise metal(s) such as aluminum, titanium, gold, nickel, nickel vanadium, alloys thereof, combinations thereof, or the like. In some embodiments, the thermal layer 210 may be formed of a single layer of material or may be formed of multiple sublayers of different materials. In some cases, the materials of the thermal layer 210 are chosen for their adhesive and/or thermally conductive properties. The materials or thicknesses of the various sublayers of the thermal layer 210 may be chosen based on considerations of thermal dissipation and/or cost, in some cases. In some cases, a thermal layer 210 comprising multiple sublayers of different materials may be considered a “thermal layer stack.” In some embodiments, the sublayers of the thermal layer 210 may have thicknesses in the range of about 250 Å to about 12000 Å, though other thicknesses are possible. In some embodiments, the total thickness of the thermal layer 210 is in the range of about 500 Å to about 30000 Å, though other thicknesses are possible. The thermal layer 210 or sublayers thereof may be formed using any suitable techniques, such as sputtering, chemical vapor deposition (CVD), atomic layer deposition (ALD), or the like.

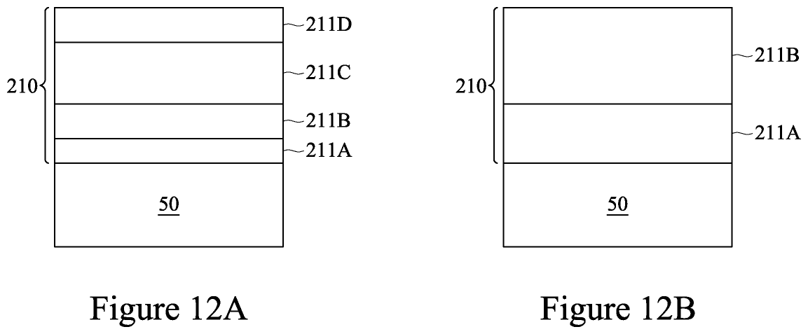

FIGS. 12A and 12B illustrate cross-sectional regions of thermal layers 210, in accordance with some embodiments. The thermal layers 210 shown in FIGS. 12A-12B are considered non-limiting examples used for illustrative purposes, and other configurations or arrangements of thermal layers 210 and sublayers thereof are possible. The thermal layers 210 are illustrated as physically contacting a top surface of a portion of an integrated circuit die 50, which may be similar to the integrated circuit dies 50A or 50B shown in FIG. 11. FIG. 12A illustrates a thermal layer 210 comprising four sublayers 211A-D, and FIG. 12B illustrates a thermal layer 210 comprising two sublayers 211A-B. Thermal layers 210 comprising more or fewer sublayers are possible.

FIG. 12A illustrates an example thermal layer 210 comprising four sublayers 211A-D, in accordance with some embodiments. In an embodiment, the sublayer 211A is a layer of aluminum having a thickness in the range of about 500 Å to about 3000 Å, the sublayer 211B is a layer of titanium having a thickness in the range of about 250 Å to about 6000 Å, the sublayer 211C is a layer of nickel vanadium having a thickness in the range of about 500 Å to about 12000 Å, and the sublayer 211D is a layer of gold having a thickness in the range of about 250 Å to about 6000 A. In some embodiments, the ratio of the thicknesses of sublayers 211A, 211B, 211C, and 211D may be about 1:0.5 to 2:1 to 4:0.5 to 2, respectively. Other materials or thicknesses are possible. In some embodiments, a sublayer may be an adhesive layer that facilitates adhesion to the integrated circuit die 50, such as sublayer 211A and/or sublayer 211B in the embodiment of FIG. 12A. In some cases, a sublayer may be formed having a greater thickness to increase thermal dissipation of the thermal layer 210, such as sublayer 211C and/or sublayer 211D in the embodiment of FIG. 12A.

FIG. 12B illustrates an example thermal layer 210 comprising two sublayers 211A-B, in accordance with some embodiments. In an embodiment, the bottom sublayer 211A is an adhesion layer, such as a layer of aluminum, titanium, or the like. In an embodiment, the top sublayer 211B is a thermal dissipation layer, such as a layer of gold, nickel vanadium or the like. Other materials are possible. In some embodiments, the bottom sublayer 211A has a thickness in the range of about 250 Å to about 6000 Å, and the top sublayer 211B has a thickness in the range of about 250 Å to about 12000 Å, though other thicknesses are possible.

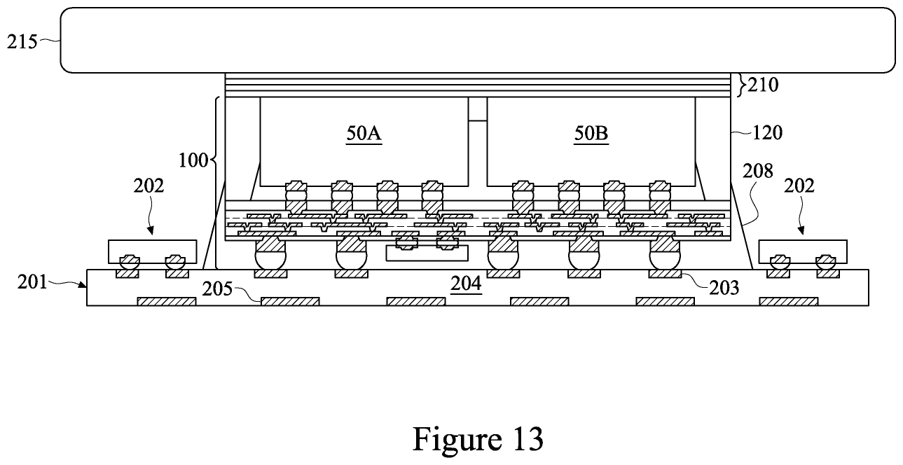

In FIG. 13, an optional temporary cover 215 is attached to the top surface of the thermal layer 210, in accordance with some embodiments. The temporary cover 215 may be, for example, a semiconductor substrate (e.g., a wafer), a dielectric substrate, a ceramic substrate, a plastic substrate, or any other suitable material. The temporary cover 215 may be attached to the thermal layer 210 using, for example, an adhesive, a release layer, or the like. The temporary cover 215 may have a substantially planar bottom surface, in some embodiments. In some embodiments, the temporary cover 215 has a width that is larger than a width of the package component 100. The temporary cover 215 may have a width that is at least as large as a width of the package substrate 201, in some cases. In this manner, the temporary cover 215 may overhang regions of the package substrate 201 around the package component 100.

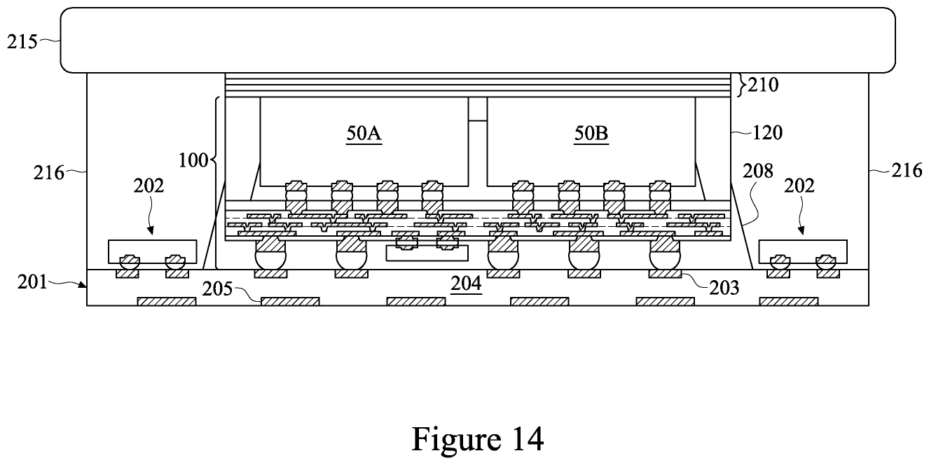

In FIG. 14, an encapsulant 216 is formed on the package substrate 201 and surrounding the package component 100, in accordance with some embodiments. The encapsulant 216 may extend on or cover sidewalls of the package component 100 and on sidewalls of the thermal layer 210. As shown in FIG. 14, the encapsulant 216 is formed between the temporary cover 215 and the package substrate 201 such that top surfaces of the thermal layer 210 and the encapsulant 216 may be substantially level or coplanar. After formation, the encapsulant 216 encapsulates the package component 100 and the SMDs 202. The encapsulant 216 may be a molding compound, epoxy, or the like. The encapsulant 216 may be applied by compression molding, transfer molding, deposition, or the like, and may be formed over the package substrate 201 such that the package component 100 and the SMDs 202 are surrounded or covered. The encapsulant 216 may be applied in liquid or semi-liquid form and then subsequently cured. In some cases, depositing an encapsulant 216 around the package component 100 can improve rigidity and reduce warpage of the package 200.

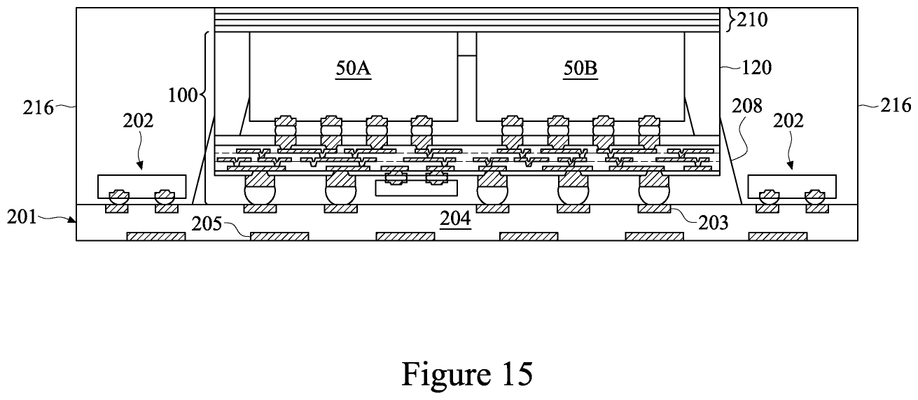

In FIG. 15, the temporary cover 215 is removed, in accordance with some embodiments. The temporary cover 215 may be removed using a suitable technique, such as etching, a planarization process (e.g., a CMP or grinding process), a thermal process, or another suitable process. In some embodiments, after removing the temporary cover 215, top surfaces of the encapsulant 216 and the thermal layer 210 may be substantially level or coplanar. In this manner, the use of a temporary cover 215 as described herein can facilitate planarity of the encapsulant 216 and the thermal layer 210. In some embodiments, after removing the temporary cover 215, a planarization process (e.g., a CMP or grinding process) may be performed on the encapsulant 216 and/or the thermal layer 210 such that top surfaces of the encapsulant 216 and the thermal layer 210 are substantially level or coplanar after the planarization process. In some embodiments, a thickness of the encapsulant 216 on the package substrate 201 is in the range of about 100 μm to about 900 μm, though other thicknesses are possible. The encapsulant 216 may have sidewalls that are coterminous with sidewalls of the package substrate 201, as shown in FIG. 15, or the sidewalls of the encapsulant 216 may be laterally offset from sidewalls of the package substrate 201. In other embodiments, the temporary cover 215 is not used.

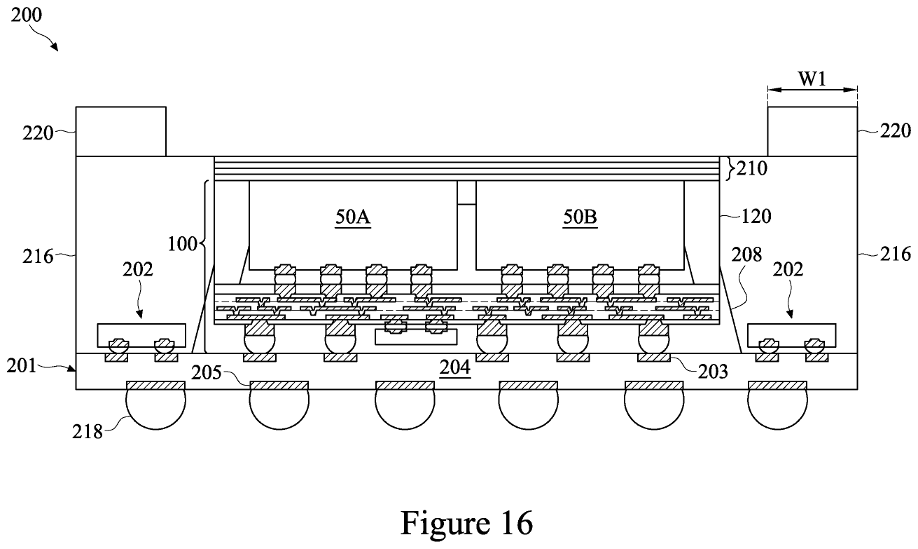

In FIG. 16, a support ring 220 is attached to the top side of the structure to form a package 200, in accordance with some embodiments. The support ring 220 is attached to improve rigidity and reduce warpage of the package 200. In some embodiments, the support ring 220 is attached to a top surface of the encapsulant 216 using an adhesive or the like. The support ring 220 may laterally encircle the package component 100. The support ring 220 may be formed of a suitably rigid material, such as stainless steel (e.g. SUS) or another metal, a ceramic material, a dielectric material, the like, or a combination thereof. The support ring 220 may have a thickness in the range of about 1 mm to about 5 mm, though other thicknesses are possible. In some embodiments, sidewalls of the support ring 220 are coterminous with sidewalls of the encapsulant 216, but in other embodiments sidewalls of the support ring 220 are laterally offset from sidewalls of the encapsulant 216. In some embodiments, the interior sidewalls of the support ring 220 are laterally separated from the thermal layer 210. The particular dimensions, location, thickness, or material of the support ring 220 may be determined according to the particular characteristics or configuration of the package 200 or the particular application thereof.

Further in FIG. 16, conductive connectors 218 may be formed on the back side conductive pads 205 of the package substrate 201, in accordance with some embodiments. The conductive connectors 218 may be similar to the conductive connectors 116 or conductive connectors 124 described previously. For example, the conductive connectors 218 may be ball grid array (BGA) connectors or the like. The conductive connectors 218 may allow the package 200 to be attached to another component, such as an interconnect substrate, a motherboard, a printed circuit board (PCB), or the like.

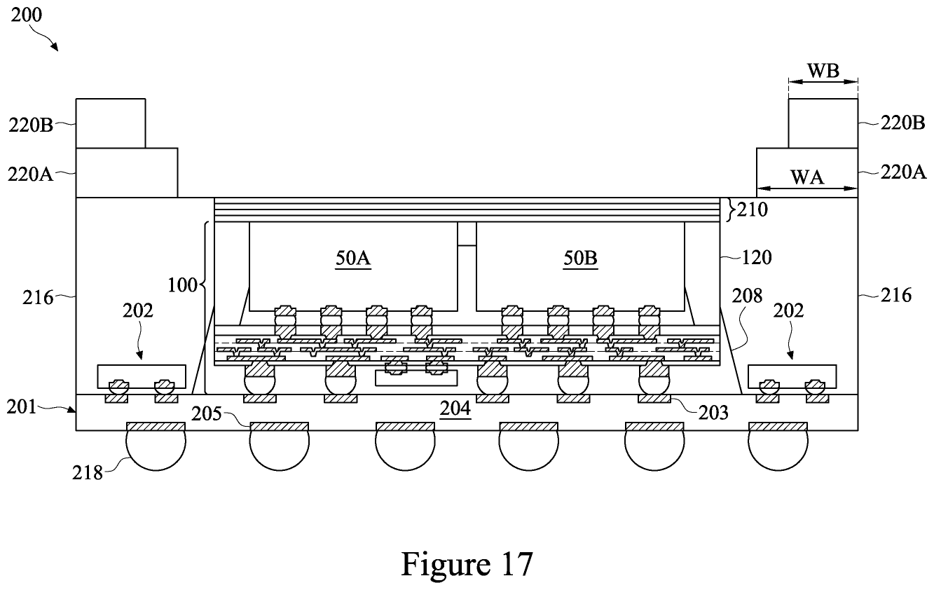

FIG. 17 illustrates a package 200 with stacked support rings 220A-B, in accordance with some embodiments. The package 200 of FIG. 17 is similar to the package 200 of FIG. 16, except that two support rings 220A-B are used rather than one support ring 220. As shown in FIG. 17, a first support ring 220A is attached to the encapsulant 216 (e.g., using an adhesive or the like), and a second support ring 220B is attached to the support ring 220A (e.g., using an adhesive or the like). The support rings 220A-B may be formed of materials similar to those described above for the support ring 220, such as metal, ceramic, etc. The first support ring 220A and the second support ring 220B may be similar materials or different materials. In some cases, using support rings 220A-B of different materials or having different material characteristics can reduce warpage of the package 200. For example, the rigidity, the Young's modulus, the coefficient of thermal expansion (CTE), or other characteristics of the materials of the support rings 220A-B may be different. The support rings 220A-B may each have a thickness in the range of about 1 mm to about 5 mm, though other thicknesses are possible. The support rings 220A-B may have similar thicknesses or different thicknesses. In some embodiments, the second support ring 220B may have a cross-sectional width WB that is about the same as or less than a cross-sectional width WA of the first support ring 220A. Sidewalls of the support rings 220A-B may be coterminous or laterally offset. The particular dimensions, locations, thicknesses, or materials of the support rings 220A-B may be determined according to the particular characteristics or configuration of the package 200 or the particular application thereof.

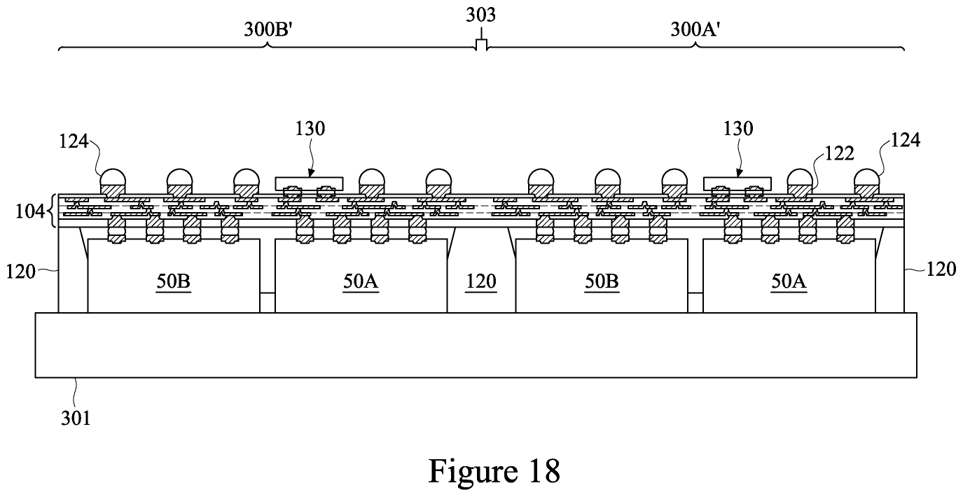

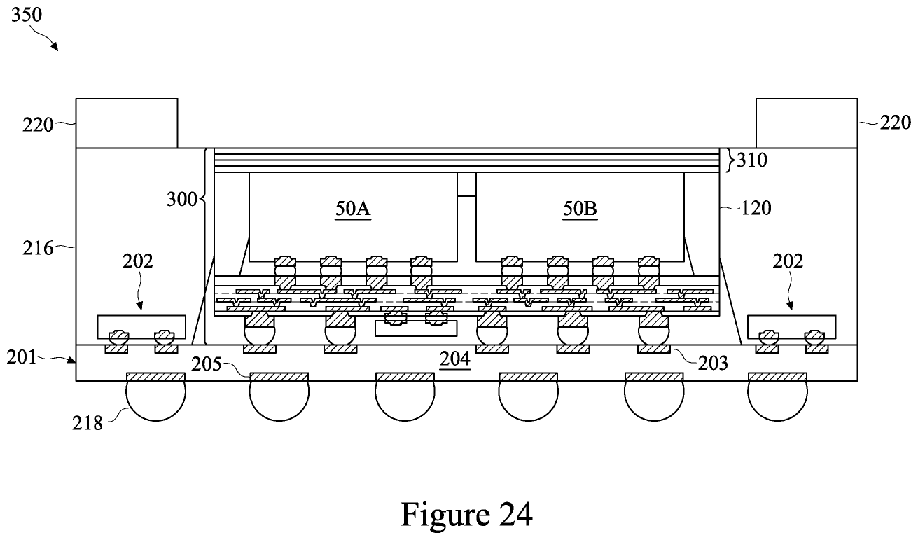

FIGS. 18 through 24 illustrate cross-sectional views of intermediate steps during a process for forming a package 350 (see FIG. 24), in accordance with some embodiments. The completed package 350 may be similar to the package 200 described for FIG. 16. The process steps for forming the package 350 may include materials, structures, and techniques similar to those described previously in FIGS. 1-16 for forming the package 200. Accordingly, some details may not be repeated during the description below for forming the package 350.

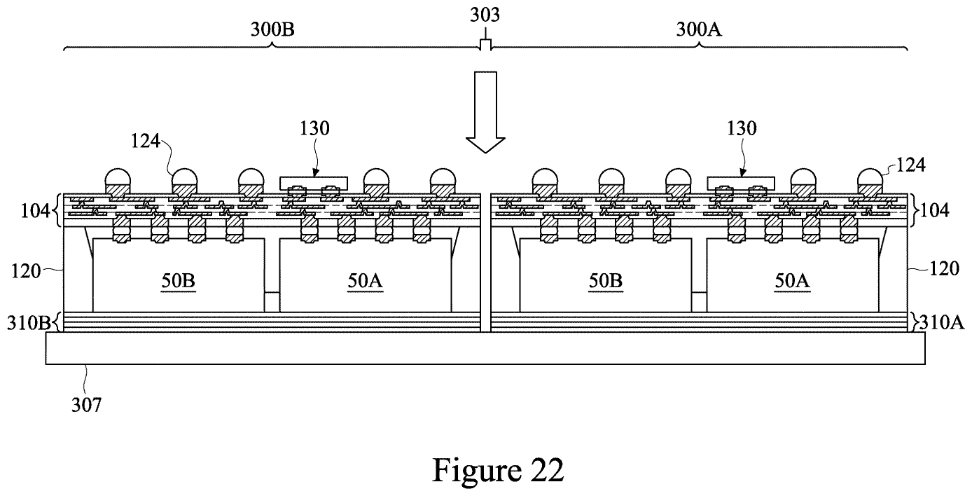

FIGS. 18 through 22 illustrate intermediate steps in the formation of package components 300A-B (see FIG. 22) on package regions 300A′ and 300B′ of a carrier substrate 301, in accordance with some embodiments. The carrier substrate 301 may be similar to the carrier substrate 101 or the carrier substrate 103 described previously. For example, the carrier substrate 301 may be a semiconductor substrate, a glass substrate, or the like. In some embodiments, multiple package components 300 are formed on the carrier substrate 301 and are subsequently singulated into individual package components 300. For example, FIG. 18 illustrates a first package region 300A′ in which a first package component 300A is formed and a second package region 300B′ in which a second package component 300B is formed. The first package region 300A′ and the second package region 300B′ are separated by a scribe region 303. The structure formed on the carrier substrate 301 shown in FIG. 18 may be formed using techniques similar to those described previously in FIGS. 1-6 for forming the structure on the carrier substrate 103 of FIG. 6. For example, a redistribution structure 104 may be formed on another carrier substrate, integrated circuit dies 50 (e.g., integrated circuit dies 50A-B) may be bonded to the redistribution structure 104, the integrated circuit dies 50 may be encapsulated by an encapsulant 120, and the structure may be flipped over and attached to the carrier substrate 301. Conductive connectors 124 and passive devices 130 may also be formed on the back side of the redistribution structure 104.

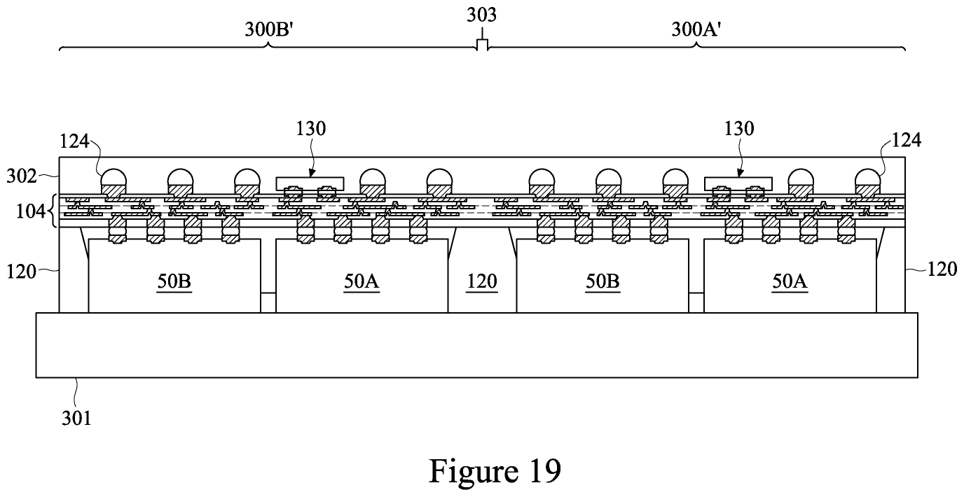

In FIG. 19, a protective material 302 is formed over the back side of the redistribution structure 104, in accordance with some embodiments. The protective material 302 may cover and surround the UBMs 122, the conductive connectors 124, and the passive devices 130. The protective material 302 protects the UBMs 122, the conductive connectors 124, and the passive devices 130 during subsequent process steps. In some embodiments, the protective material 302 may be a polymer, a polyimide, a photoresist, an anti-reflection coating, the like, or another suitable material. In some embodiments, a planarization process (e.g., a CMP or grinding process) may be performed to planarize the surface of the protective material 302.

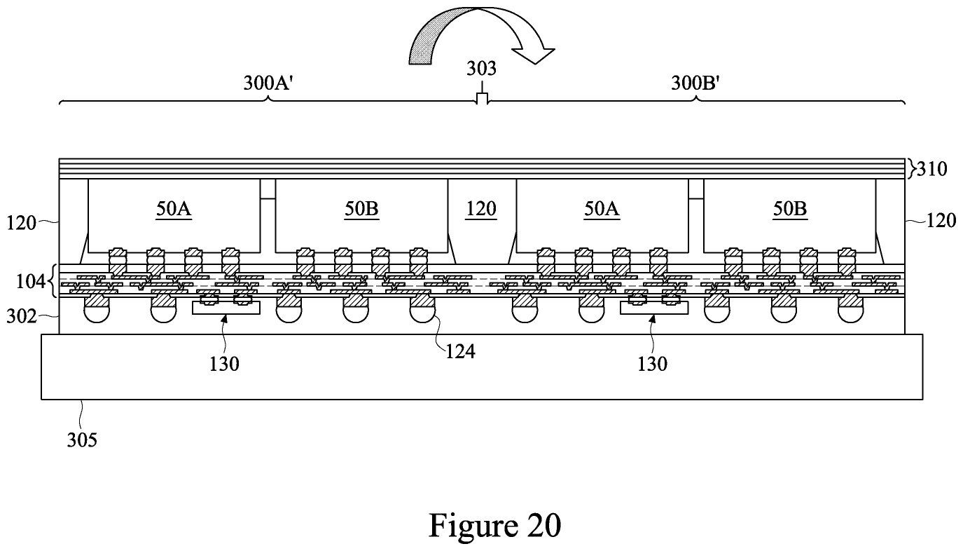

In FIG. 20, the structure is removed from the carrier substrate 301, flipped over, and attached to another carrier substrate 305, in accordance with some embodiments. The carrier substrate 305 may be similar to carrier substrates described previously, such as a glass substrate or the like. The protective material 302 may be attached to the carrier substrate 305 using an adhesive, release layer, or the like. A thermal layer 310 is then formed over the top side of the structure, in accordance with some embodiments. The thermal layer 310 may be similar to the thermal layer 210 described previously for FIGS. 11-12B. For example, the thermal layer 310 may comprise multiple sublayers of different metals. The thermal layer 310 may physically contact top surfaces of the encapsulant 120 and/or the integrated circuit dies 50. As shown in FIG. 20, the thermal layer 310 extends continuously over the first package region 300A′, the second package 300B′, and the scribe region 303.

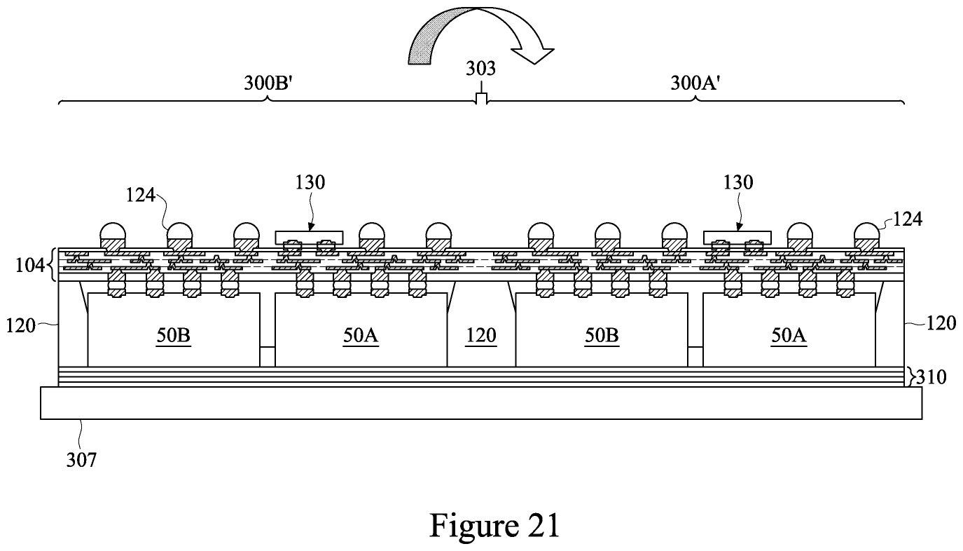

In FIG. 21, the structure is removed from the carrier substrate 305, flipped over, and attached to a carrier 307, in accordance with some embodiments. The carrier 307 may be similar to the carrier substrates described previously, or may be a die attach film (DAF), tape, or the like. After attaching the structure to the carrier 307, the protective material 302 may be removed using a suitable technique, such as etching, ashing, a chemical rinse, or the like.

In FIG. 22, a singulation process is performed in the scribe region 303 to separate the first package component 300A from the second package component 300B. The singulation process may comprise, for example, a mechanical sawing process, a laser sawing process, a plasma sawing process, an etching process, the like, or a combination thereof. The singulation process also singulates the thermal layer 310 such that the first package component 300A has a thermal layer 310A covering its top surface (facing down in FIG. 22) and the second package component 300B has a thermal layer 310B covering its top surface (facing down in FIG. 22). In this manner, the thermal layer 310 is formed prior to singulation. The package components 300A-B may then be removed from the carrier 307.

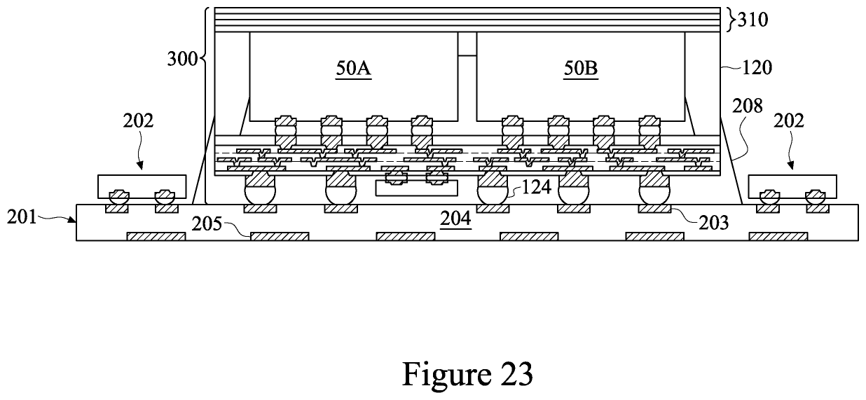

In FIG. 23, a package component 300 is attached to a package substrate 201, in accordance with some embodiments. The package component 300 may be similar to the package components 300A-B described for FIG. 22. The package substrate 201 may be similar to the package substrate 201 described previously for FIG. 8, and SMDs 202 may be attached to the top side of the package substrate 201. The package component 300 may be attached to the package substrate 201 using techniques similar to those described previously for FIGS. 9-10. For example, the conductive connectors 124 of the package component 300 may be placed on the conductive pads 203 of the package substrate 201, and then a reflow process may be performed to bond the package component 300 to the package substrate 201. An underfill 208 may be deposited between the package component 300 and the package substrate 201, in some embodiments. In some cases, forming the thermal layer 310 on the package component 300 before attaching the package component 300 to the package substrate 201 can provide more process flexibility.

In FIG. 24, an encapsulant 216 and a support ring 220 are formed on the package substrate 201 to form a package 350, in accordance with some embodiments. In some cases, the package 350 may be similar to the package 200 described previously for FIG. 16 or FIG. 17. The encapsulant 216 and support ring 220 may be similar to those described previously for FIGS. 13-16, and may be formed in a similar manner. For example, a temporary cover may be formed over the thermal layer 310, and the encapsulant 216 may be formed under the thermal layer 310 and surrounding the package component 300. The temporary cover may then be removed, and one or more support rings 220 then attached to the top surface of the encapsulant 216. Conductive connectors 218 may also be formed on the package substrate 201. This is an example, and other processes for forming a package 350 are possible.

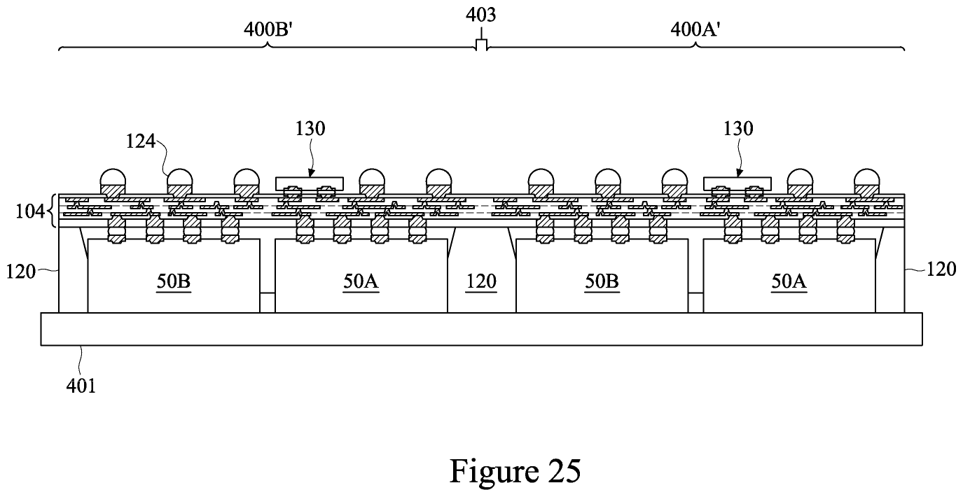

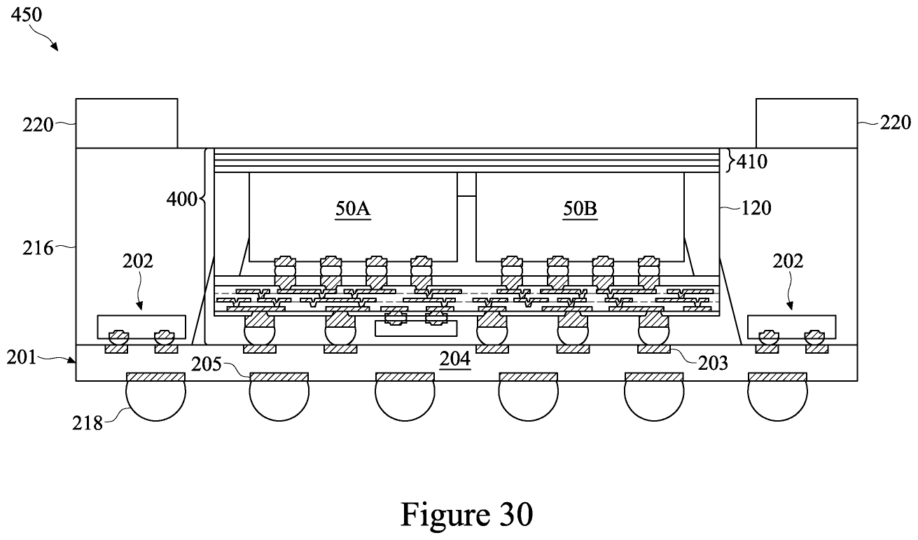

FIGS. 25 through 30 illustrate cross-sectional views of intermediate steps during a process for forming a package 450 (see FIG. 30), in accordance with some embodiments. The completed package 450 may be similar to the package 200 described for FIG. 16 or the package 350 described for FIG. 24. The process steps for forming the package 450 may include materials, structures, and techniques similar to those described previously in FIGS. 1-16 for forming the package 200. Accordingly, some details may not be repeated during the description below for forming the package 450.

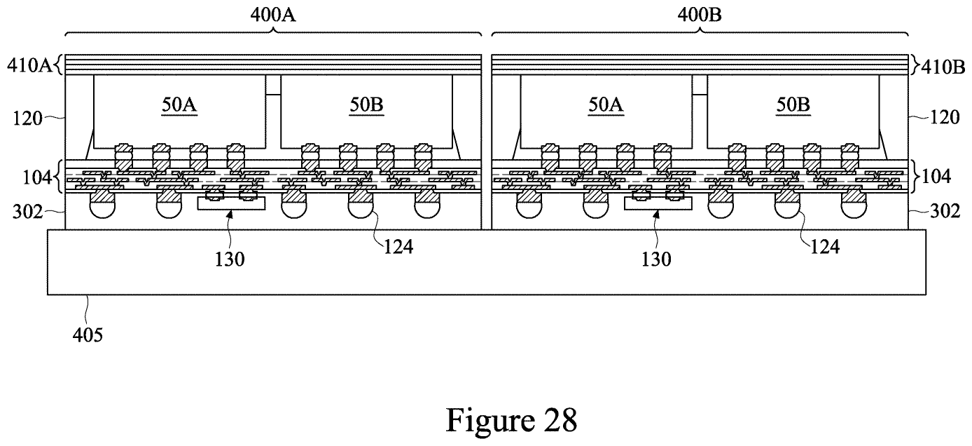

FIGS. 25 through 28 illustrate intermediate steps in the formation of package components 400A-B (see FIG. 28) on package regions 400A′ and 400B′ of a carrier 401, in accordance with some embodiments. The carrier 401 may be similar to the carrier substrates described previously, or may be a die attach film (DAF), tape, or the like. In other embodiments, the structure may be formed on another carrier substrate and transferred to the carrier 401 as shown in FIG. 25. In some embodiments, multiple package components 400 are formed on the carrier 401 and are subsequently singulated into individual package components 400. For example, FIG. 25 illustrates a first package region 400A′ in which a first package component 400A is formed and a second package region 400B′ in which a second package component 400B is formed. The first package region 400A′ and the second package region 400B′ are separated by a scribe region 403. The structure formed on the carrier 401 shown in FIG. 25 may be formed using techniques similar to those described previously in FIGS. 1-6 for forming the structure on the carrier substrate 103 of FIG. 6. For example, a redistribution structure 104 may be formed on another carrier substrate, integrated circuit dies 50 (e.g., integrated circuit dies 50A-B) may be bonded to the redistribution structure 104, the integrated circuit dies 50 may be encapsulated by an encapsulant 120, and the structure may be flipped over and attached to the carrier 401. Conductive connectors 124 and passive devices 130 may also be formed on the back side of the redistribution structure 104.

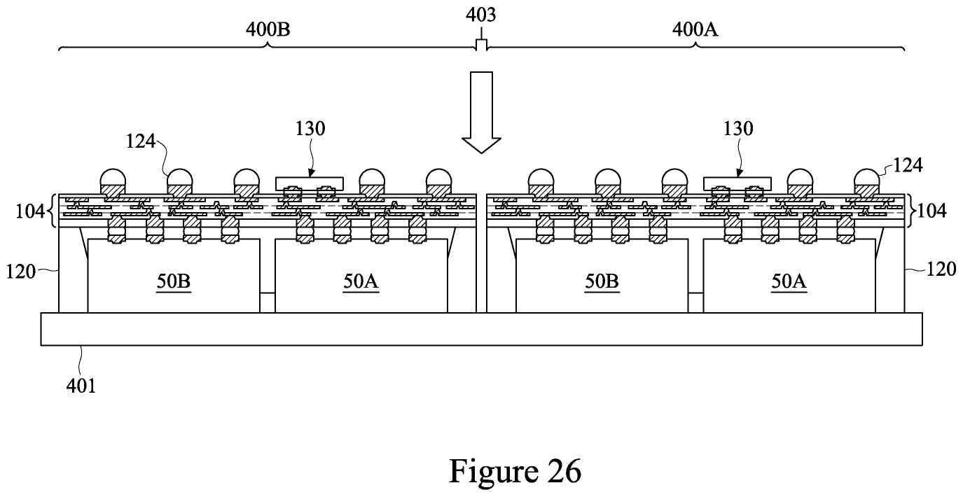

In FIG. 26, a singulation process is performed in the scribe region 403 to separate the first package component 400A from the second package component 400B. The singulation process may comprise, for example, a mechanical sawing process, a laser sawing process, a plasma sawing process, an etching process, the like, or a combination thereof.

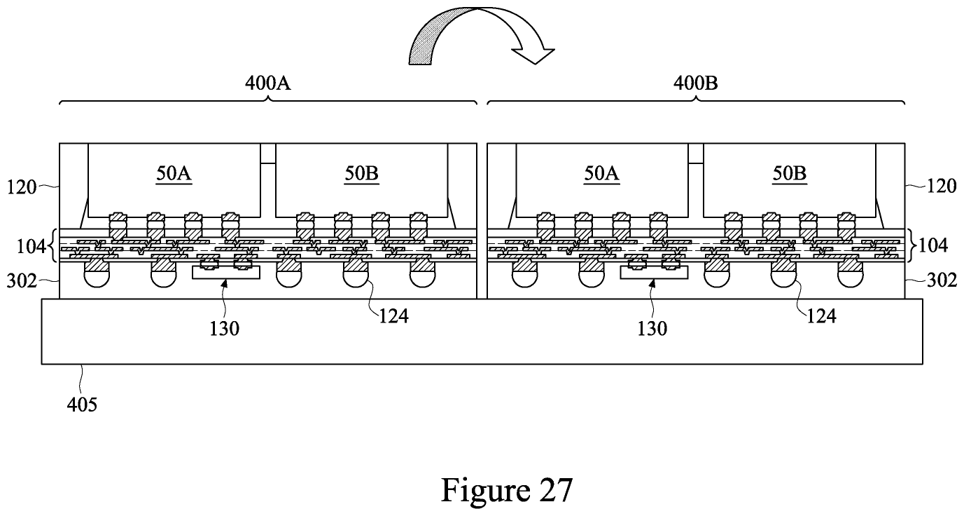

In FIG. 27, the package components 400A-B are removed from the carrier 401, flipped over, and attached to a carrier substrate 405. The carrier substrate 405 may be similar to carrier substrates described previously, such as a glass substrate or the like. In some embodiments, before attaching the package components 400A-B to the carrier substrate 405, a protective material 302 may be deposited over the redistribution structure 104, the conductive connectors 124, and the passive devices 130. The protective material 302 may be similar to the protective material 302 described previously for FIG. 19.

In FIG. 28, thermal layers 410A-B are formed over the top side of the package components 400A-B, in accordance with some embodiments. For example, a first thermal layer 410A is formed over the first package component 400A, and a second thermal layer 410B is formed over the second package component 400B. The thermal layers 410A-B may be similar to the thermal layer 210 described previously for FIGS. 11-12B. For example, the thermal layers 410A-B may comprise multiple sublayers of different metals. The thermal layers 410A-B may physically contact top surfaces of the encapsulant 120 and/or the integrated circuit dies 50 of the package components 400A-B.

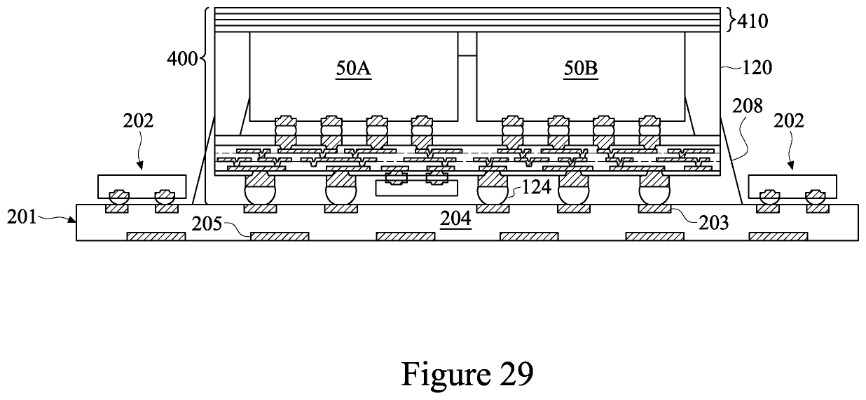

In FIG. 29, a package component 400 is attached to a package substrate 201, in accordance with some embodiments. The package component 400 may be similar to the package components 400A-B described for FIG. 28. The package substrate 201 may be similar to the package substrate 201 described previously for FIG. 8, and SMDs 202 may be attached to the top side of the package substrate 201. The package component 400 may be attached to the package substrate 201 using techniques similar to those described previously for FIGS. 9-10. For example, the conductive connectors 124 of the package component 400 may be placed on the conductive pads 203 of the package substrate 201, and then a reflow process may be performed to bond the package component 400 to the package substrate 201. An underfill 208 may be deposited between the package component 400 and the package substrate 201, in some embodiments. In some cases, forming the thermal layer 410 on the package component 400 before attaching the package component 400 to the package substrate 201 can provide more process flexibility.

In FIG. 30, an encapsulant 216 and a support ring 220 are formed on the package substrate 201 to form a package 450, in accordance with some embodiments. In some cases, the package 450 may be similar to the package 200 described previously for FIG. 16 or FIG. 17. The encapsulant 216 and support ring 220 may be similar to those described previously for FIGS. 13-16, and may be formed in a similar manner. For example, a temporary cover may be formed over the thermal layer 410, and the encapsulant 216 may be formed under the thermal layer 410 and surrounding the package component 400. The temporary cover may then be removed, and one or more support rings 220 then attached to the top surface of the encapsulant 216. Conductive connectors 218 may also be formed on the package substrate 201. This is an example, and other processes for forming a package 450 are possible.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments may achieve advantages. For example, forming a thermal layer as described herein on a package component of a package can improve heat dissipation and thus improve thermal performance of the package. The thermal layer may be formed directly on the integrated circuit dies of the package component to improve heat dissipation away from the integrated circuit dies. The thermal layer may be formed as part of a variety of manufacturing steps for forming a package, and thus can allow for process flexibility. Covering the package substrate and surrounding the package component with an encapsulant can improve package rigidity and reduce warpage. Attaching a support ring as described herein can reduce warpage for a package, including thermally-induced warpage. In some cases, a stack of support rings as described herein can reduce warpage even further. The techniques described herein can allow for improved thermal performance and reduced warpage of large packages, such as packages having an area five times the reticle size or larger.

In an embodiment, a method includes forming a thermal layer stack covering a top surface of a package component, wherein the thermal layer stack includes sublayers of different metals; connecting the package component to a package substrate; depositing a molding material on the package substrate and on the package component; and attaching a support ring to the molding material. In an embodiment, the package component includes a redistribution structure, dies bonded to the redistribution structure, and an encapsulant laterally surrounding the dies. In an embodiment, the molding material laterally surrounds the package component and the thermal layer stack. In an embodiment, the thermal layer stack is formed on the top surface of the package component after the package component is connected to the package substrate. In an embodiment, the molding material physically contacts a sidewall of the package component and a sidewall of the thermal layer stack. In an embodiment, top surfaces of the molding material and the thermal layer stack are level. In an embodiment, the thermal layer stack includes a sublayer of nickel vanadium over a sublayer of aluminum. In an embodiment, the thermal layer stack includes a sublayer of gold over a sublayer of titanium.

In an embodiment, a method includes forming a package component, including bonding an integrated circuit die to a redistribution structure; and depositing a first molding material on the redistribution structure and along a sidewall of the integrated circuit die, wherein a top surface of the integrated circuit die is free of the first molding material; bonding the package component to a package substrate; and depositing a second molding material on the package substrate and along a sidewall of the package component, wherein the top surface of the integrated circuit die is free of the second molding material. In an embodiment, the method includes attaching a first support ring to the molding material. In an embodiment, the second molding material physically contacts a sidewall of the first molding material. In an embodiment, a top surface of the second molding material is farther from the package substrate than the top surface of the package component. In an embodiment, the method includes depositing a metallic adhesion layer on the top surface of the integrated circuit die and on a top surface of the first molding material and depositing a metallic thermal layer on the metallic adhesion layer. In an embodiment, the metallic adhesion layer includes at least one of group of metals including titanium and aluminum, and wherein the metallic thermal layer includes at least one of a group of metals including nickel vanadium and gold. In an embodiment, a top surface of the metallic thermal layer and a top surface of the second molding material are level.

In an embodiment, a package includes a package component attached to a substrate, wherein the package component includes a semiconductor die bonded to a redistribution structure; and a first molding material on the redistribution structure and laterally surrounding the semiconductor die; a second molding material on the substrate and laterally surrounding the package component; and a first support ring on the second molding material, wherein a bottom surface of the first support ring is farther from the substrate than a top surface of the package component. In an embodiment, the package includes a second support ring on the first support ring. In an embodiment, the package includes a metal layer extending on top surfaces of the semiconductor die and the first molding material. In an embodiment, the metal layer includes sublayers of different metals. In an embodiment, a top surface of the second molding material is free of the metal layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package comprising:
a redistribution structure;
a first semiconductor die attached to the redistribution structure;
a first molding material over the redistribution structure and surrounding the first semiconductor die;
a stack of metal layers on a top surface of the first molding material and on a top surface of the first semiconductor die;
a second molding material surrounding the first molding material and the stack of metal layers; and
a first support ring on a top surface of the second molding material.

2. The package of claim 1, wherein the first semiconductor die is separated from the second molding material by the first molding material.

3. The package of claim 1, wherein the stack of metal layers comprises first metal layer over a second metal layer, wherein the first metal layer and the second metal layer are different metals.

4. The package of claim 1, wherein the first metal layer is an adhesion layer comprising titanium or aluminum.

5. The package of claim 1, wherein the stack of metal layers and the first molding material have coterminous sidewalls.

6. The package of claim 1, further comprising a second support ring on a top surface of the first support ring.

7. The package of claim 1, further comprising a package substrate attached to the redistribution structure, wherein the second molding material is between the package substrate and the first support ring.

8. The package of claim 1, wherein top surfaces of the first semiconductor die and the first molding material are level.

9. A structure comprising:
a package substrate;
a package component attached to the package substrate;
a metallic thermal layer covering a top surface of the package component;
a first encapsulant over the package substrate, wherein the first encapsulant encapsulates the package component, wherein top surfaces of the first encapsulant and the metallic thermal layer are level; and
a support ring attached to the first encapsulant.

10. The structure of claim 9, wherein a width of the support ring is greater than a width of the metallic thermal layer.

11. The structure of claim 9, wherein sidewalls of the package component are free of the metallic thermal layer.

12. The structure of claim 9, wherein the package component comprises a die, wherein the metallic thermal layer covers a top surface of the die.

13. The structure of claim 9, further comprising a surface mount device attached to the package substrate, wherein the first encapsulant covers the surface mount device.

14. The structure of claim 9, wherein the first encapsulant covers sidewalls of the metallic thermal layer.

15. The structure of claim 9, wherein the metallic thermal layer comprises a plurality of metallic sublayers.

16. A method comprising:
bonding a package component to a package substrate, wherein the package component comprises an integrated circuit die;
after bonding the package component, depositing a first metal layer over a top surface of the package component, wherein the first metal layer physically contacts a top surface of the integrated circuit die;
depositing a second metal layer over a top surface of the first metal layer, wherein the first metal layer, the second metal layer, and the package component have a same width;
depositing a molding material over a top surface of the package substrate and along sidewalls of the first metal layer, the second metal layer, and the package component; and
bonding a support structure to the molding material.

17. The method of claim 16, wherein a top surface of the second metal layer is free of the molding material.

18. The method of claim 16, wherein the second metal layer is closer to the package substrate than the support structure.

19. The method of claim 16, wherein the support structure comprises a ring-shaped structure.

20. The method of claim 16, wherein the second metal layer comprises gold or vanadium.
